(19) United States
(12) Patent Application Publication
(10) Pub. No.: US 2009/0310640 A1
(43) Pub. Date: Dec. 17, 2009

(54) MOCVD GROWTH TECHNIQUE FOR PLANAR SEMIPOLAR (Al, In, Ga, B)N BASED LIGHT EMITTING DIODES

(75) Inventors: Hitoshi Sato, Kanagawa (JP); Roy B. Chung, Goleta, CA (US); Feng Wu, Goleta, CA (US); James S. Speck, Goleta, CA (US); Steven P. DenBaars, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: The Regents of the University of California, Oakland, CA (US)

(21) Appl. No.: 12/419,128

(22) Filed: Apr. 6, 2009

Related U.S. Application Data
(60) Provisional application No. 61/042,639, filed on Apr. 4, 2008.

(51) Int. Cl. H01S 5/343; H01L 29/66; H01L 33/00; H01L 21/20

(52) U.S. Cl. 372/45.011; 257/14; 257/13; 438/46; 257/E29.168; 257/E33.008; 257/E21.09

(57) ABSTRACT

A III-nitride optoelectronic device comprising a light emitting diode (LED) or laser diode with a peak emission wavelength longer than 500 nm. The III-nitride device has a dislocation density, originating from interfaces between an indium containing well layer and barrier layers, less than 9×10⁹ cm⁻². The III-nitride device is grown with an interruption time, between growth of the well layer and barrier layers, of more than 1 minute.

### CROSS REFERENCE TO RELATED APPLICATIONS

This application claims the benefit under 35 U.S.C. Section 119(e) of co-pending and commonly-assigned U.S. Provisional Patent Application Ser. No. 61/042,639, filed on Apr. 4, 2008, by Hitoshi Sato, Roy B. Chung, Feng Wu, James S. Speck, Steven P. DenBaars and Shuji Nakamura, entitled “MOCVD GROWTH TECHNIQUE FOR PLANAR SEMIPOLAR (Al, In, Ga, B)N BASED LIGHT EMITTING DIODES,” attorney's docket number 30794.274-US-P1 (2008-534), which application is incorporated by reference herein.

This application is related to co-pending and commonly-assigned U.S. Utility patent application Ser. No. ______, filed on same date herewith, by Hitoshi Sato, Hirohiko Hirasawa, Roy B. Chung, Steven P. DenBaars, James S. Speck and Shuji Nakamura, entitled “METHOD FOR FABRICATION OF SEMIPOLAR (Al,In,Ga,B)N BASED LIGHT EMITTING DIODES,” attorneys' docket number 30794.264-US-P1 (2008-415-1), which which application claims the benefit under 35 U.S.C. Section 119(e) of U.S. Provisional Application Ser. No. 61/042,644, filed on Apr. 4, 2008, by Hitoshi Sato, Hirohiko Hirasawa, Roy B. Chung, Steven P. DenBaars, James S. Speck and Shuji Nakamura, entitled “METHOD FOR FABRICATION OF SEMIPOLAR (Al,In,Ga,B)N BASED LIGHT EMITTING DIODES,” attorneys' docket number 30794.264-US-P1 (2008-415-1);

which applications are incorporated by reference herein.

### BACKGROUND OF THE INVENTION

1. Field of the Invention

This invention relates to fabricating high power and high efficiency nitride Light Emitting Diodes (LEDs), especially in the range of wavelength from 560 nm to 680 nm, and nitride-based white LEDs.

2. Description of the Related Art

(Note: This application references a number of different publications as indicated throughout the specification by one or more reference numbers within brackets, e.g., [Ref(s). x]. A list of these different publications ordered according to these reference numbers can be found below in the section entitled “References.” Each of these publications is incorporated by reference herein.)

Current nitride technology for electronic and optoelectronic devices employs nitride films grown along the polar c-direction. However, conventional c-plane quantum well structures in III-nitride based optoelectronic and electronic devices suffer from the undesirable quantum-confined Stark effect (QCSE), due to the existence of strong piezoelectric and spontaneous polarizations. The strong built-in electric fields along the c-direction cause spatial separation of electrons and holes that in turn give rise to restricted carrier recombination efficiency, reduced oscillator strength, and red-shifted emission.

One approach to eliminating the spontaneous and piezoelectric polarization effects in GaN optoelectronic devices is to grow the devices on nonpolar planes of the crystal. Such planes contain equal numbers of Ga and N atoms and are charge-neutral. Furthermore, subsequent nonpolar layers are crystallographically equivalent to one another so the crystal will not be polarized along the growth direction. Two such families of symmetry-equivalent nonpolar planes in GaN are the {11-20} family, known collectively as a-planes, and the {1-100} family, known collectively as m-planes. Unfortunately, despite advances made by researchers at the University of California, growth of nonpolar nitrides remains challenging and has not yet been widely adopted in the III-nitride industry.

Another approach to reducing, or possibly eliminating, the polarization effects in GaN optoelectronic devices is to grow the devices on semipolar planes of the crystal. The term semipolar planes can be used to refer to a wide variety of planes that possess two nonzero h, i, or k Miller indices, and a nonzero l Miller index. Some commonly observed examples of semipolar planes in c-plane GaN heteroepitaxy include the {11-22}, {10-11}, and {10-13} planes, which are found in the facets of pits. These planes also happen to be the same planes that the authors have grown in the form of planar films. Other examples of semipolar planes in the wurtzite crystal structure include, but are not limited to, {10-12}, {20-21} and {10-14} planes. The nitride crystal's polarization vector lies neither within such planes or normal to such planes, but rather lies at some angle inclined relative to the plane's surface normal. For example, the {10-11} and {10-13} planes are at 62.98° and 32.06° to the c-plane, respectively.

In addition to spontaneous polarization, the second form of polarization present in nitrides is piezoelectric polarization. This occurs when the material experiences a compressive or tensile strain, as can occur when (Al, In, Ga, B)N layers of dissimilar composition (and therefore different lattice constants) are grown in a nitride hetero-structure. For example, a thin AlGaN layer on a GaN template will have in-plane tensile strain, and a thin InGaN layer on a GaN template will have in-plane compressive strain, both due to lattice matching to the GaN. Therefore, for an InGaN quantum well on GaN, the piezoelectric polarization will point in the opposite direction to the spontaneous polarization of the InGaN and GaN. For an AlGaN layer latticed matched to GaN, the piezoelectric polarization will point in the same direction as the spontaneous polarization of the AlGaN and GaN.

The advantage of using semipolar or nonpolar planes over c-plane nitrides is that the total polarization will be reduced. There may even be zero polarization for specific alloy compositions on specific planes. Such scenarios will be discussed in detail in future scientific papers. The important point is that the polarization will be reduced compared to the polarization of c-plane nitride structures. A reduced polarization field allows growth of a thicker quantum well. Hence higher Indium composition and thus longer wavelength emission can be realized by nitride LEDs. Many efforts have been made in order to fabricate semipolar/nonpolar based nitride LEDs in longer wavelength emission regimes [Refs. 1-4].

This disclosure describes an invention allowing for fabrication of blue, green, yellow, and amber LEDs on semipolar or nonpolar (Al, In, Ga, B)N semiconductor crystals. So far, no nitride LEDs have been successful at longer wavelength emission in the yellow and amber regions. However, the present invention, which will be discussed in more detail in the following sections, demonstrates promising results for commercialization of nitride-based yellow and amber LEDs.

### SUMMARY OF THE INVENTION

The present invention describes a method for growing planar blue, green, yellow, white, and other color Light Emitting Diodes (LEDs) with a bulk semipolar and nonpolar GaN substrate such as {10-1-1}, {11-22}, {1100}, and other planes. Semipolar and nonpolar (Al, In, Ga, B)N semiconductor crystals allow the fabrication of a multilayer structure with zero, or reduced, internal electric fields resulting from internal polarization discontinuities within the structure, as described in previous disclosures. This invention describes high quality crystal growth of LED or laser diode structures using an intentional interruption time introduced between Indium containing well layer growth and barrier layer growth of a multi-quantum well (MQW) or a single quantum well (SQW), by a Metal Organic Chemical Vapor Deposition (MOCVD) technique. This allows controllability over Indium incorporation into the well layer of indium containing layer(s) of the semipolar or nonpolar based planar LEDs or laser diodes. The use of a semipolar or nonpolar (Al, In, Ga, B)N semiconductor orientation results in reduced internal electric field and thus thicker quantum well and higher indium composition for longer wavelength emissions relative to [0001] nitride semiconductors.

To overcome the limitations in the prior art described above, and to overcome other limitations that will become apparent upon reading and understanding the present specification, the present invention discloses a III-nitride based optoelectronic device grown on a nonpolar or semipolar plane substrate, comprising an LED or laser diode with an indium containing III-nitride quantum well layer (e.g., InGaN), a peak emission wavelength longer than 500 nm (e.g., longer than 550 nm), and a dislocation density, originating from interfaces between the quantum well layer and barrier layers, less than 9×10⁹ cm² (e.g., less than 1×10⁶ cm⁻²).

Alternatively, the dislocation density is sufficiently low to obtain an output power of the light of at least 3.5 mW at an operating current of 20 mA.

The LED may be grown on a nonpolar or semipolar plane of the substrate that enables an indium composition and/or thickness of the quantum well layer such that the quantum well layer is capable of emitting the light having the peak emission wavelength longer than 500 nm.

The LED or laser diode may have a semipolar orientation, for example. If the quantum well layer is semipolar (or nonpolar), then an amount of piezoelectric and spontaneous polarization of the well layer may be reduced as compared to a piezoelectric and spontaneous polarization of a c-plane indium containing quantum well layer. Alternatively, the indium containing quantum well layer's piezoelectric and spontaneous polarization vector lies in the plane of the interface(s), or at an angle less than 90 degrees inclined relative to interface(s) of the indium containing well layer with barrier layer(s), or in a direction that causes a QCSE that is reduced as compared a QCSE created by a piezoelectric and spontaneous polarization vector aligned with a c-axis, thereby enabling the light having a wavelength longer than 500 nm.

The LED or laser diode may be grown on the substrate that is a miscut nonpolar or semipolar plane substrate. For example, the optoelectronic device may be grown on a surface of the substrate, wherein the surface is at an angle with respect to a nonpolar or semipolar plane that maintains a semipolar or nonpolar property of the quantum well layer. For example, the surface is a miscut surface and the angle is a miscut angle.

As noted above, more generally, the present invention discloses a semipolar or nonpolar light emitting device, comprising a III-nitride quantum well layer with a reduced internal electric field and higher indium composition for longer wavelength emissions, relative to [0001] III-nitride semiconductors.

The present invention further discloses a light emitting device, comprising a first cladding layer material having a first cladding layer energy band; a second cladding layer material having a second cladding layer energy band; an active layer material for emitting light having a wavelength longer than 500 nm and having an active layer energy band, wherein the active layer material is between the first cladding layer material and the second cladding layer, and the first cladding material, second cladding material, and active layer material are such that the optical output power decreases, as a temperature of the light emitting device increases, to a lesser degree than the optical output power from the AlInGaP light emitting device.

The present invention further discloses a method of fabricating a III-nitride optoelectronic device, comprising growing the nonpolar or semipolar device with a period of interruption time of more than 5 seconds (e.g., more than 1 minute) between a well layer and barrier layers. A carrier gas may be nitrogen (N₂) or hydrogen (H₂), for example, during the period of interruption time.

### BRIEF DESCRIPTION OF THE DRAWINGS

Referring now to the drawings in which like reference numbers represent corresponding parts throughout:

FIG. 1 is a flow chart of the preferred embodiment of this invention.

FIGS. 2(a) and 2(b) are graphs of interruption time dependence of emission wavelength of LEDs grown on c-plane (c-LED) and semipolar plane GaN substrates ((11-22) LED), wherein both FIGS. 2(a) and 2(b) show the electroluminescence (EL) intensity (arbitrary units, a.u.) as a function of emission wavelength from the LED (nm) for a 5 second (sec) interruption time and a 10 minute (min) interruption time, respectively, the c-LED in FIG. 2(a) emits at a peak emission wavelength of 497 nm and an output power of 1.06 mW, the c-LED in FIG. 2(b) emits at a peak emission wavelength of 433 nm and an output power of 0.32 mW, the (11-22) LED in FIG. 2(a) emits at a peak emission wavelength of 493 nm and an output power of 1.34 mW, the (11-22) LED in FIG. 2(b) emits at a peak wavelength of 589 nm and an output power of 0.13 mW, the operating current for the LEDs in FIG. 2(a) is a 20 mA direct current (DC), the c-LED in FIG. 2(b) is grown on a (0001) plane, the (11-22) LED in FIG. 2(b) is grown on a (11-22) plane, the c-LED in FIG. 2(a) is grown on c-GaN bulk, and the (11-22) LED in FIG. 2(a) is grown on a (11-22) plane of (11-22) oriented GaN bulk.

FIGS. 3(a) and 3(b) are cross-section Transmission Electron Micrograph (TEM) images of semipolar LED samples S071212 DB (left, FIG. 3(a), peak emission wavelength λ=680 nm) with a short interruption time (1 minute) and S071216DA (right, FIG. 3(b), peak emission wavelength λ=540 nm) with a long interruption time (10 minutes), wherein the length of the bar in the inset is equivalent to 160 nm in an actual length scale of a sample.

FIG. 4 is a graph of interruption time dependence of emission wavelength in an active region of a quantum well structure of the LEDs, wherein EL intensity (a.u.) is plotted as a function of emission wavelength from the LED (nm), wherein sample S071216DA, grown with an interruption time of 10 minutes, emits light having a peak emission wavelength of 556 nm at an output power of 0.57 mW, and sample S071212 DB, grown with an interruption time of 1 minute, emits light having a peak wavelength of 680 nm with an output power of approximately ˜20 microwatts (μW), and both samples are driven with a DC operating current of 20 mA.

FIG. 5(a) is a graph of output power (mW) vs. operating current (mA) for an InGaN based LED (S071020DE No. 2) and an AlInGaP based 5 millimeter (mm) lamp, and FIG. 5(b) is a graph of temperature dependence (degrees Celsius, ° C.) of the relative output power (normalized intensity) of AlInGaP and InGaN LEDs, wherein this comparison has been done with a commercial AlInGaP yellow LED and InGaN yellow LED made by the present invention, the output power of both LEDs was normalized to be one at a temperature of 0° C., and normalized intensity vs. temperature is plotted for the AlInGaP LED emitting yellow light at an operating current of 1 mA (solid diamonds), the AlInGaP LED emitting yellow light at an operating current of 20 mA (hollow or open triangles), the InGaN LED emitting yellow light at an operating current of 1 mA (solid squares), and the InGaN LED emitting yellow light at an operating current of 20 mA (hollow or open squares).

FIG. 6 is a schematic cross section of a light emitting device of the present invention.

FIG. 7 is a band structure of a device of the present invention, plotting band energy as a function of position through device layers.

FIG. 8(a) is a schematic illustrating polar, nonpolar, and semipolar planes.

FIG. 8(b) illustrates polarization discontinuity calculated for InGaN coherently strained to GaN, after [Ref. 5], wherein the curves (1), (2), (3), and (4) are for Indium compositions in the InGaN of 0.05, 0.10, 0.15, and 0.20, respectively.

FIG. 9(a) is a schematic of c-plane GaN and InGaN, FIG. 9(b) is an energy band diagram of the structure in FIG. 9(a), FIG. 9(c) is a schematic of a-plane GaN and InGaN, and FIG. 9(d) is an energy band diagram of the structure in FIG. 9(c).

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention allows the growth of planar LEDs with longer wavelength emission (500 nm or higher) by incorporating more Indium in the well layer (InₓGa₁₋ₓN) of a MQW or SQW, using MOCVD or MBE growth techniques. This will be an important method for fabricating and commercializing high power and high efficient nitride LEDs, especially in the range of wavelength from 560 nm to 680 nm, and nitride-based white LEDs.

Current AlInGaP-based yellow and amber LEDs are not suitable for high temperature and high injection current operations due to carrier overflow due to the small conduction band offset between the active region and the cladding layer. Temperature dependence of the output power of InGaN-based LEDs is less sensitive and hence it operates more efficiently and with more stability.

Technical Description

Process Steps

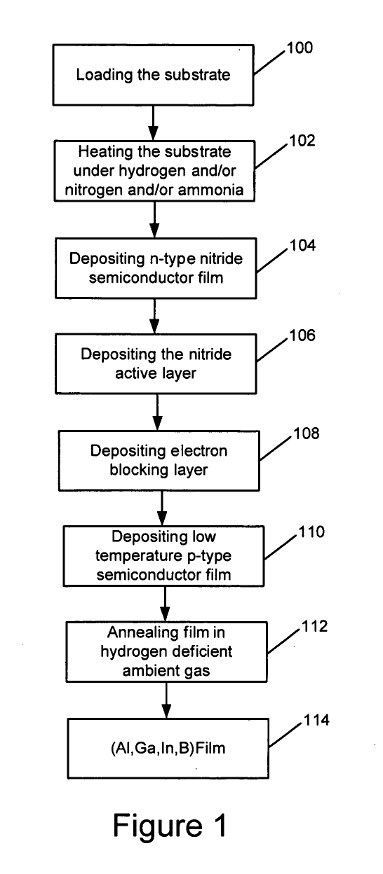

The present invention describes a method for growth of planar LED structures on semipolar {10-1-1} and/or {11-22} GaN via MOCVD. FIG. 1 is a flowchart that illustrates the steps of a MOCVD process for depositing semipolar GaN thin films on a {10-1-1} and {11-22} bulk GaN substrate, according to the preferred embodiment of the present invention that is described in the following paragraphs.

Block 100 represents loading the substrate. For the growth of a semipolar LED structure, a bulk {10-1-1} or {11-22} GaN substrate is loaded into an MOCVD reactor.

Block 102 represents the step of heating the substrate under hydrogen and/or nitrogen and/or ammonia. The reactor's heater is then turned on and ramped to a set point temperature under hydrogen and/or nitrogen. Generally, nitrogen and/or hydrogen flow over the substrate at atmospheric pressure.

Block 104 represents depositing a n-type nitride semiconductor film (e.g., n-type GaN) on the substrate. After the heating step of block 102, the temperature is set to 1100° C. and 54 μmol/minute of Trimethylgallium (TMGa) is introduced into the reactor with DiSilane for 30 minutes to initiate the growth of n-type GaN. 4 slm of Ammonia (NH₃) is also introduced at this stage and the ammonia level is kept at the constant level until the end of the growth.

Block 106 represents depositing the nitride active layer. Once the desired n-type GaN thickness is achieved in block 104, the reactor's temperature set point is decreased to 815° C., and 6.9 μmol/minute of Triethylgallium (TEGa) is introduced into the reactor and a 20 nm thick GaN barrier layer is grown. Once the desired thickness of GaN barrier is achieved, 10.9 μmol/minute of TMIn is introduced into the reactor to deposit a 3 nm thick quantum well. After the deposition of the InGaN layer, 6.9 μμmol/minute of TEGa is again introduced into the reactor for growth of a GaN barrier to finalize the quantum well structure. Between the InGaN well growth and GaN barrier growth, intentional interruption is introduced and the duration varies from 1 minute to 10 minutes depending on the desired Indium composition. This step can be repeated several times to form MQWs. Thus, the present invention discloses a method of fabricating a III-nitride optoelectronic device, comprising growing the nonpolar or semipolar device with a period of interruption time of more than 5 seconds between a well layer and barrier layers. The period of interruption time may be more than 1 minute, and use a carrier gas such as Nitrogen (N₂) or hydrogen (H₂) during the period of interruption time.

Block 108 represents depositing an electron blocking layer on the active layer of block 106. Once the SQW/MQW is deposited, 3.6 μmol/minute of TMGa, 0.7 μmol/minute of Trimethylaluminum (TMAl), and 2.36×10⁻² μmol/minute of Cp₂Mg are introduced into the reactor in order to form a 10 nm-thick AlGaN electron blocking layer which is slightly doped with Mg.

Block 110 represents depositing low temperature nitride p-type semiconductor (e.g., p-type GaN, or p-GaN) on the blocking layer. Once a desired AlGaN thickness is achieved in block 108, the reactor's set point temperature is maintained at 820° C. for 10 minutes. For the first 3 minutes of this interval, 12.6 μmol/minute of TMGa and 9.8×10⁻² μmol/minute of Cp₂Mg are introduced into the reactor. For the last 7 minutes, the flow of Cp₂Mg is doubled. Then the temperature is ramped to 875° C. in 1 minute, and TMGa flow is kept at the same constant level and Cp₂Mg is reduced back to 9.8×10⁻² μmol/minute during this ramp time. The growth of p-GaN is continued at 875° C. for another 1 minute. The end result is a nitride diode with longer wavelength emission.

Block 112 represents annealing the p-type film of block 110 in a hydrogen deficient ambient gas. Once the reactor has cooled, the epitaxial wafer of nitride diode grown in blocks 100-110 is removed and annealed in a hydrogen deficient ambient for 15 minutes at a temperature of 700° C. in order to activate Mg doped GaN.

Block 114 represents the end result, a nitride (Al, In, Ga, B)N diode with longer wavelength emission, e.g., a semipolar or nonpolar light emitting device, comprising a III-nitride quantum well layer with a reduced internal electric field, increased thickness, and/or higher indium composition for longer wavelength emissions, relative to [0001] III-nitride semiconductors. In one example, the device is a III-nitride based optoelectronic device grown on a nonpolar or semipolar substrate, comprising an LED or laser diode with an indium containing III-nitride quantum well layer, a peak emission wavelength longer than 500 nm, and a dislocation density, originating from interfaces between the indium containing III-nitride quantum well layer and III-nitride barrier layers, less than 9×10⁹ cm⁻².

Experimental Results

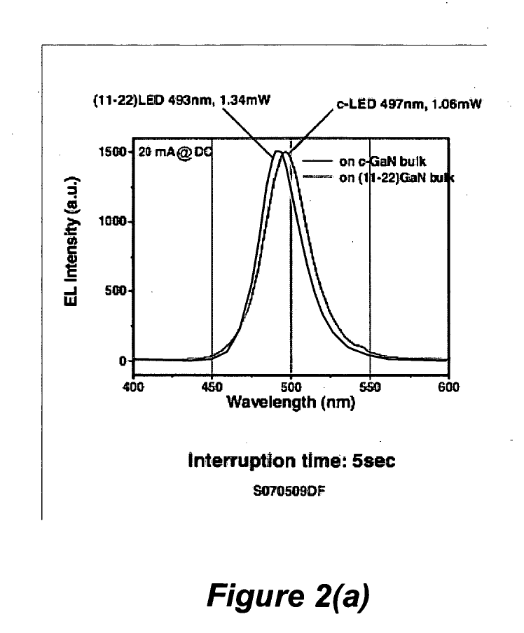

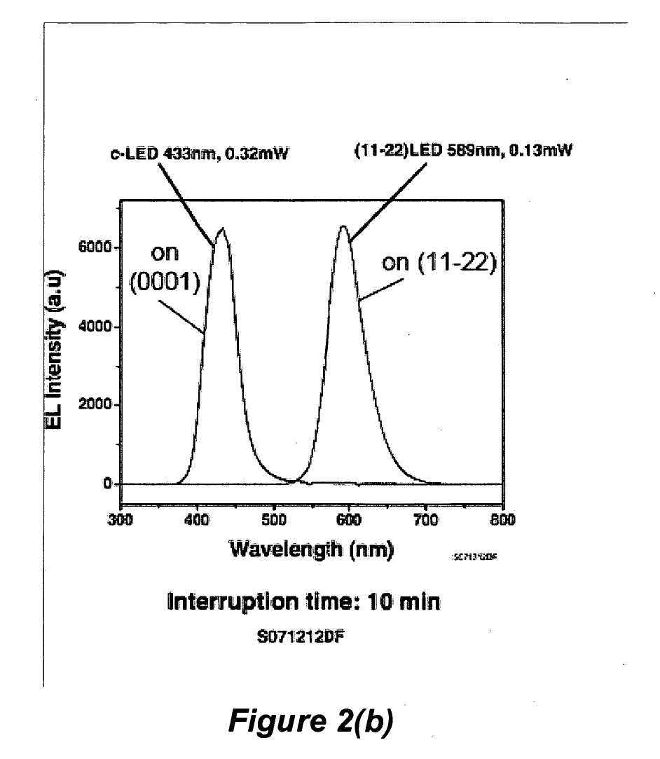

In order to observe the effect of the interruption time, LEDs were grown on two bulk GaN substrates with different orientations—c-plane and semipolar plane—in the same MOCVD reactor. FIGS. 2(a) and 2(b) illustrate the relation between interruption time and emission wavelength from LEDs grown on bulk c-planes and semipolar planar LEDs grown on semipolar bulk GaN substrates. FIG. 2(a) on the left shows that both c-plane and semi-polar planes can achieve LEDs emitting a peak emission wavelength at around 495 nm. However, with longer interruption time (e.g., 10 minutes, as shown in FIG. 2(b)), the peak emission wavelength of the c-plane sample (c-LED) has become shorter due to severe Indium desorption. On the other hand, the semipolar sample ((11-22) LED) shows emission at 589 nm under a longer (e.g., 10 minute) interruption condition. While the physical explanations are still under the investigation, the long interruption time between growth of the quantum well and the barrier layers seems to be effective in obtaining a strong emission in a long wavelength region using a certain orientation of bulk GaN substrates. Therefore, in order to obtain long wavelength emission, such as for yellow LED or laser diodes, the growth needs to be done on a bulk semipolar or nonpolar GaN substrate with a certain interruption time between growth of the well and barrier layers.

Possible Modifications and Variations

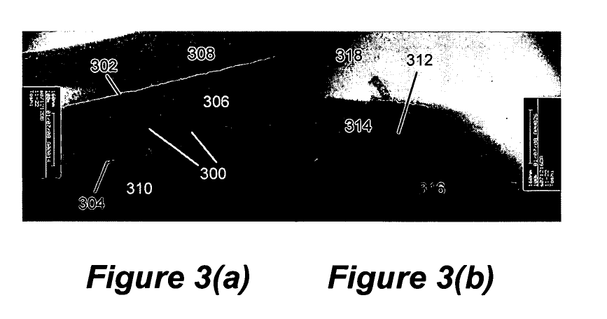

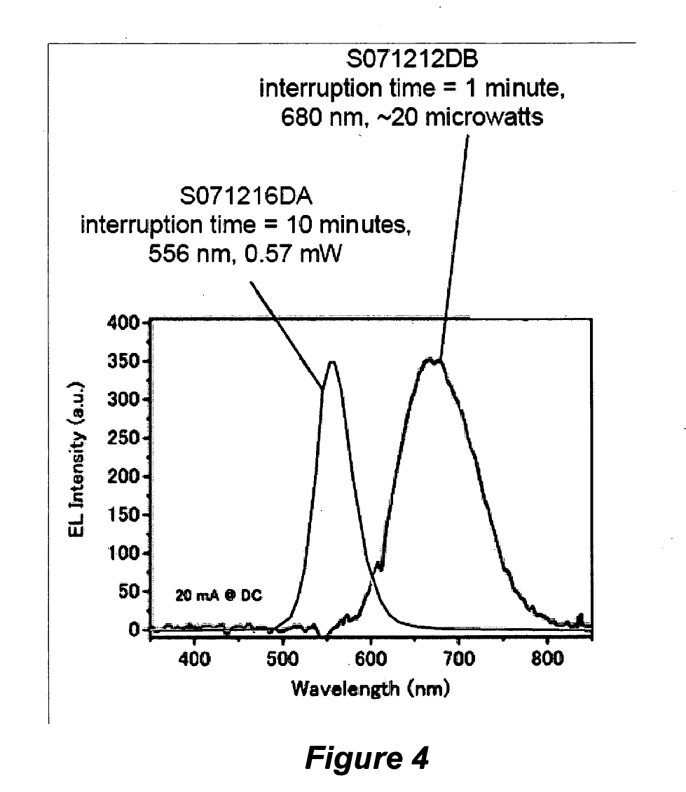

Images shown in FIGS. 3(a) and 3(b) were taken by Transmission Electron Microscopy and illustrate the threading dislocations of the quantum well structure for the planar LED sample (S071212 DB) emitting light with a peak emission wavelength at 680 nm (FIG. 3(a)), and for the almost dislocation-free planar LED (S071216DA) emitting light with a peak emission wavelength at 540 nm (FIG. 3(b)). The sample S071212 DB was grown with shorter interruption time (1 minute, see FIG. 4), showing the huge number of dislocations 300 originating from the interfaces 302, 304 between the InGaN quantum well 306 and GaN barrier layers 308, 310. The dislocation 300 density of sample S071212 DB was approximately 9×10⁹ cm⁻². On the other hand, the dislocation density 312 (in the InGaN quantum well 314 between GaN barriers 316, 318) of the sample S071216DA was less than 1×10⁶ cm⁻². The present invention believes that the dislocations 300 observed in S071212 DB originate due to excess Indium in the InGaN well layers 306 that dissociates during the subsequent GaN barrier 308 or p-AlGaN or p-GaN growth periods, or due to excess Indium that induces strain on following layers e.g., 308.

The output powers of the yellow and amber LED (S071216DA) and the red LED (S071212 DB) were measured, and are illustrated in FIG. 4. The output power of the yellow LED with a long interruption time (e.g., 10 minutes in FIG. 4) and low dislocation density (S071216DA) was about thirty times larger than that of the red LED (S071212 DB) with a short interruption time (e.g., 1 minute in FIG. 4) and large number of dislocations.

Advantages and Improvements

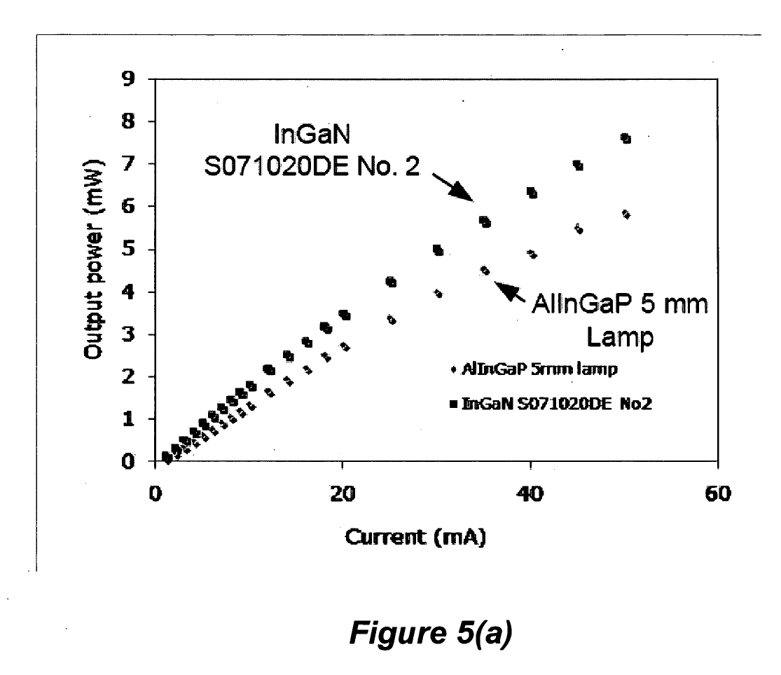

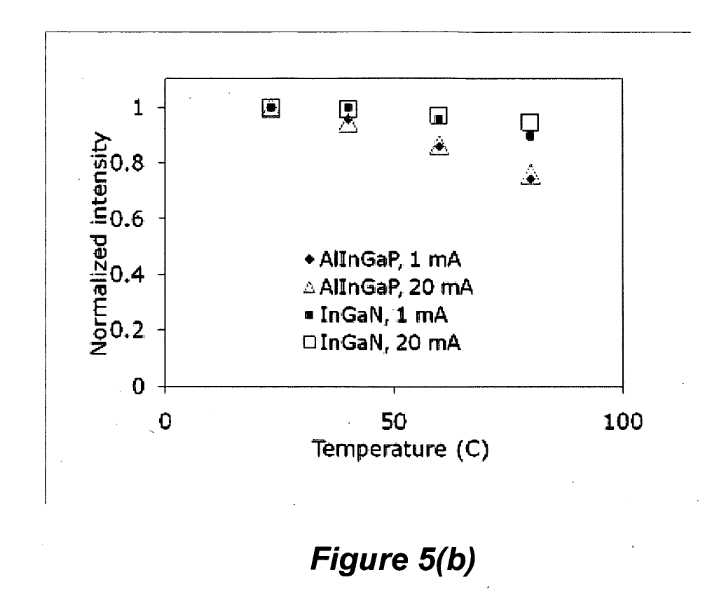

The existing practice has not been able to produce nitride-based planar high-power LEDs emitting light at longer wavelength (500 nm or above). The only commercially available LEDs at longer wavelength are AlInGaP-based LEDs in the amber region. However, the disadvantage of AlInGaP-based LEDs is their temperature-sensitive operation due to carrier overflow from the active regions, illustrated in FIGS. 5(a) and 5(b). When the ambient temperature becomes higher, the output power of AlInGaP LEDs is decreased dramatically due to increased carrier overflow from the active layer to cladding layers (wherein the carrier overflow is due to a small energy band offset between the active layer and the cladding layers), as shown in FIG. 5(b). Also, the output power of the AlInGaP LEDs is easily saturated for the same reason (due to the carrier overflow) when the operating current increased, as shown in FIG. 5(a). On the other hand, the output power of InGaN based LEDs shows a smaller temperature dependence of the output power and a small output power saturation (due to a relatively large energy band offset between the active layer and the cladding layer) when the operating current increased.

Another disadvantage of AlInGaP technology is that (Al, In, Ga)P alloys cannot produce shorter wavelength LEDs in the blue and near ultraviolet regions, while InGaN quantum well can cover from near ultraviolet to microwave regions. Therefore, having controllability of Indium composition for nitride LEDs can broaden the spectrum of semipolar and nonpolar-based Nitride LEDs and replace current AlInGaP based LEDs in the longer wavelength region.

As described in previous sections, interruption time between the growth of the well layer (InGaN) and the barrier layer (GaN) has shown promising results, with a lower dislocation density, for making high-power semipolar-based nitride LEDs in the yellow and amber regions. By engineering the bandgap of active layers, combinations of more than two layers with different bandgaps can produce multi-color LEDs, including a white LED on a single chip, without having to combine many chips together. Hence, it will be possible to fabricate high-power and high efficiency planar white LEDs, and other colors, solely based on nitride LEDs grown on semipolar GaN substrates.

LED Structure

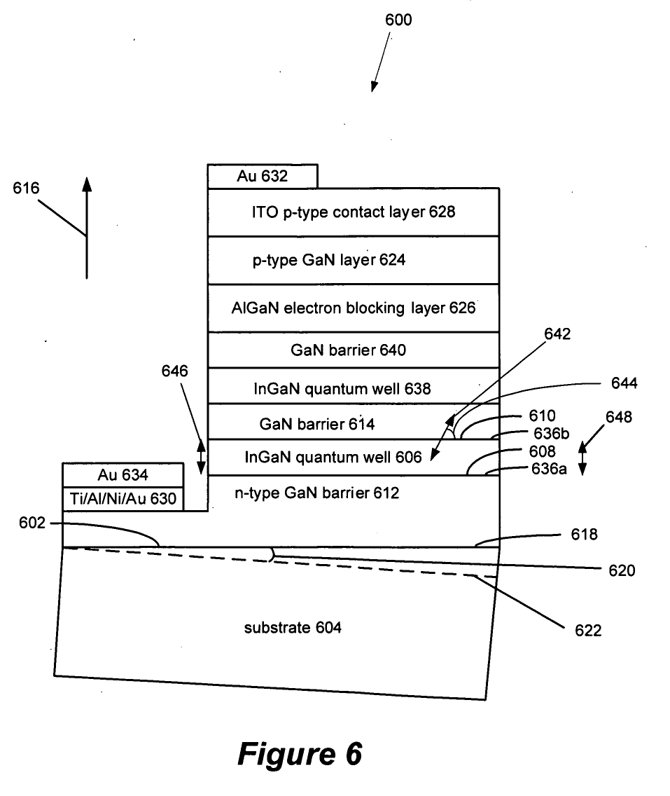

FIG. 6 illustrates a III-nitride based optoelectronic device 600 grown on a nonpolar or semipolar plane 602 of a substrate (e.g., III-nitride or other suitable substrate) 604, or on a nonpolar or semipolar substrate 604, comprising an LED or laser diode with an indium containing III-nitride quantum well layer (e.g., InGaN) 606, having a peak emission wavelength longer than 500 nm (or, e.g., longer than 550 nm), and a dislocation density, originating from interfaces 608, 610 between the indium containing III-nitride quantum well layer 606 and III-nitride barrier layers (e.g., GaN) 612, 614, less than 9×10⁹ cm⁻².

In one embodiment, the LED 600 or laser diode has a semipolar orientation 616, for example, by growing the LED 600 epitaxially in the semipolar direction 616 on the top surface 618, which is a semipolar plane 602, of the substrate 604. If the well layer 606 is semipolar, the well can have an amount of piezoelectric and spontaneous polarization reduced as compared to a piezoelectric and spontaneous polarization of a c-plane indium containing III-nitride quantum well layer.

The LED or laser diode 600 may be grown on the substrate that is a miscut nonpolar or semipolar plane substrate 604. For example, the optoelectronic device 600 may be grown on a surface 618 of the substrate 604, wherein the surface 618 is at an angle 620 with respect to a nonpolar or semipolar plane 622 and the surface 618 maintains a semipolar or nonpolar property of the quantum well 606. In this case the surface 618 is a miscut surface and the angle 620 is a miscut angle. However, the surface 618 is not limited to miscut surfaces, and can include angled surfaces obtained by other means.

The barrier layer 612 is typically also an n-type III-nitride (e.g., n-type GaN) layer. Also shown is a p-type III-nitride layer (e.g., Mg doped GaN) 624, electron blocking layer 626 (e.g., Mg doped AlGaN), p-type contact layer (e.g., ITO) 628, n-type contacts (e.g., Ti/Al/Ni/Au) 630, and metallization 632, 634 (e.g., Au). The top or growth surface 636a of the n-type layer 612, or top surface 636b of the quantum well 606, and/or interfaces 608, 610, may a semipolar plane, or be angled with respect to a semipolar plane so long as the quantum well 606 maintains a semipolar or nonpolar property. Also shown are an additional quantum well (e.g., InGaN) 638 and barrier layer 640 (e.g., GaN), thereby forming a MQW.

FIG. 6 also illustrates that the indium containing quantum well layer's 606 piezoelectric and spontaneous polarization vector direction 642 may lie in the plane of the interfaces 608, 610, or at an angle 644, less than 90 degrees, inclined relative to interface(s) 608, 610, of the indium containing well layer 606 with barrier layer(s) 612, 614. Thus, the indium containing well quantum layer's 606 piezoelectric and spontaneous polarization vector direction 642 may lie in a direction that causes a QCSE that is reduced as compared a QCSE created by a piezoelectric and spontaneous polarization vector 642 aligned with a c-axis, thereby enabling the light having the peak wavelength that is longer than 500 nm.

The LED may emit light (from the well layer 606), having a peak emission wavelength longer than 550 nm. The nonpolar or semipolar plane 602, or orientation 618, or orientation of the polarization vector 642, enables an indium composition of, thickness 646 of, and/or QCSE (or polarization field) within, the indium containing well layer 606 such that the indium containing quantum well layer 606 is capable of emitting the light having the peak emission wavelength longer than 500 nm, or even longer than 550 nm.

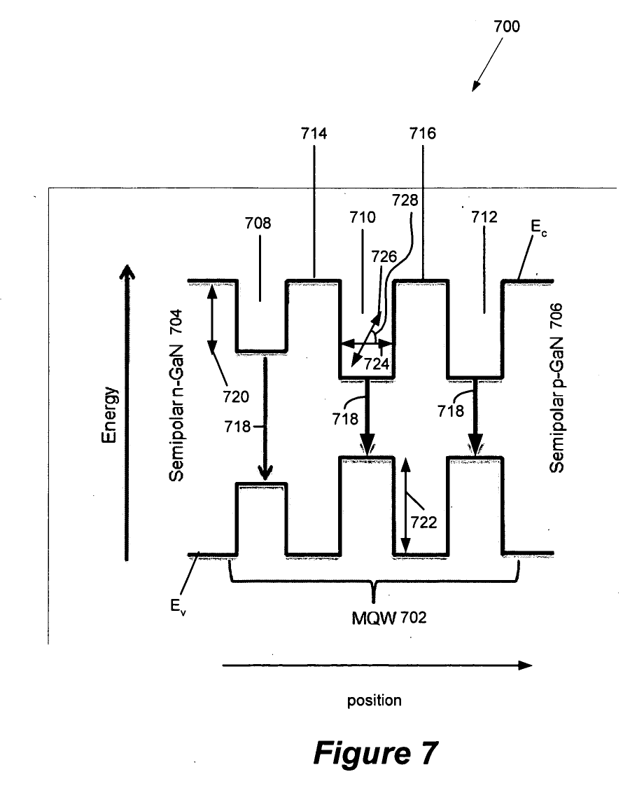

FIG. 7 is the band structure of an LED device 700 according to the present invention, illustrating the conduction energy band E_{c}, valence energy band Eᵥ, MQW structure 702 between a semipolar n-type GaN (n-GaN) layer 704 and semipolar p-type GaN (p-GaN) layer 706, wherein the MQW structure 702 comprises one or more quantum wells or active layers 708, 710, 712 (e.g., InGaN) and barrier layers or cladding layers 714, 716, 704, 706 (e.g., GaN). The device 700 thus comprises a first cladding layer material 714 having a first cladding layer energy band; a second cladding layer material 716 having a second cladding layer energy band (typically the first cladding material 714 and second cladding material 716 are the same); an active layer material 708, 710, 712 for emitting light 718 having a wavelength longer than 500 nm and having an active layer energy band, wherein the active layer material 708, 710, 712 is between the first cladding layer material 714 and the second cladding layer material 716, and the first cladding material 714, second cladding material 716, and active layer material 710 are such that an optical output power of the light saturates, as an operating current is increased, to a lesser degree than an optical output power from an AlInGaP light emitting device (FIG. 5(a)), and the optical output power decreases, as a temperature of the light emitting device increases, to a lesser degree than the optical output power from the AlInGaP light emitting device (FIG. 5(b)).

Furthermore, the first cladding material 714, second cladding material 716, and active layer material 710 may be such a first energy band offset 720 between the active layer energy band and the first cladding layer energy band, and a second energy band offset 722 between the active layer energy band and the second cladding layer energy band, may be smaller than an AlInGaP energy band offset between an AlInGaP active layer energy band and an AlInGaP cladding layer energy band in an AlInGaP light emitting device. Typically the first energy band offset 720 and second energy band offset 722 are the same.

FIGS. 6 and 7 also illustrate an embodiment of a light emitting device 600, 700, comprising a III-nitride quantum well layer 606, 710 with a reduced internal electric field, increased thickness 646, and higher indium composition for longer wavelength emissions, relative to [0001] III-nitride semiconductors. The device 600 may further comprise the III-nitride quantum well layer 606 between III-nitride barrier layers 612, 614 having a larger bandgap than the quantum well layer 606, such that electrons and holes are quantum mechanically confined in the quantum well layer 606 along a direction, e.g., 648, 724 between the barrier layers 612,614,714, 716; and a position or orientation of group III atoms and nitrogen atoms relative to one another within the quantum well layer 606, such that the quantum well layer's piezoelectric and spontaneous polarization vector 642, 726 caused by positive ionic charge on the group III atoms and negative charge on the nitrogen atoms, lies at a nonzero angle 728 inclined relative the direction 648, 724 between the barrier layers 612, 614, thereby reducing a QCSE as compared to a QCSE created by a polarization vector aligned with the c-axis.

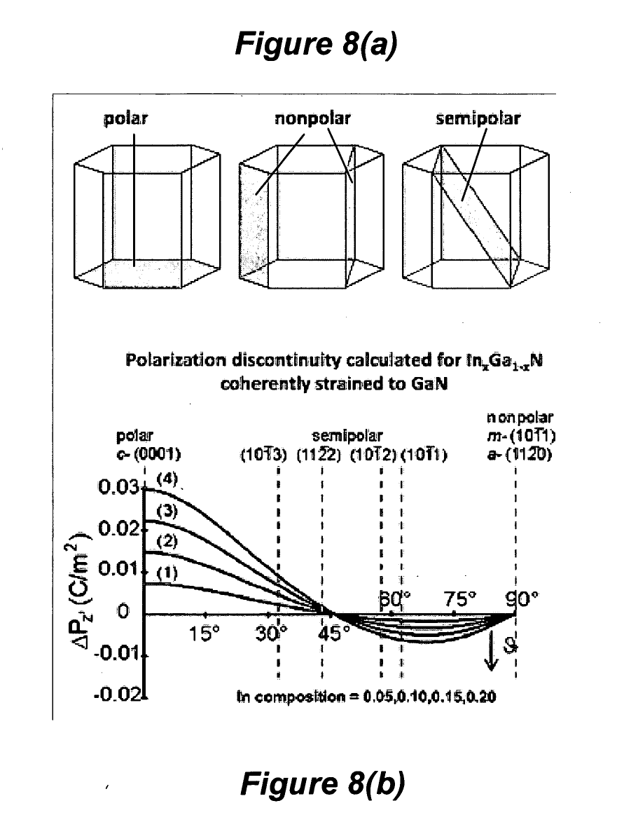

FIG. 8(a) illustrates polar, nonpolar and semipolar planes in a wurtzite III-nitride crystal, and FIG. 8(b) is a graph illustrating calculated polarization ΔP_{z} in InₓGa₁₋ₓN (0≦x≦1) along the direction 648 between the barriers 612, 614, as a function of the orientation of the GaN plane upon which the InGaN is grown, for different indium compositions x=0.05, 0.10, 0.15, and 0.20.

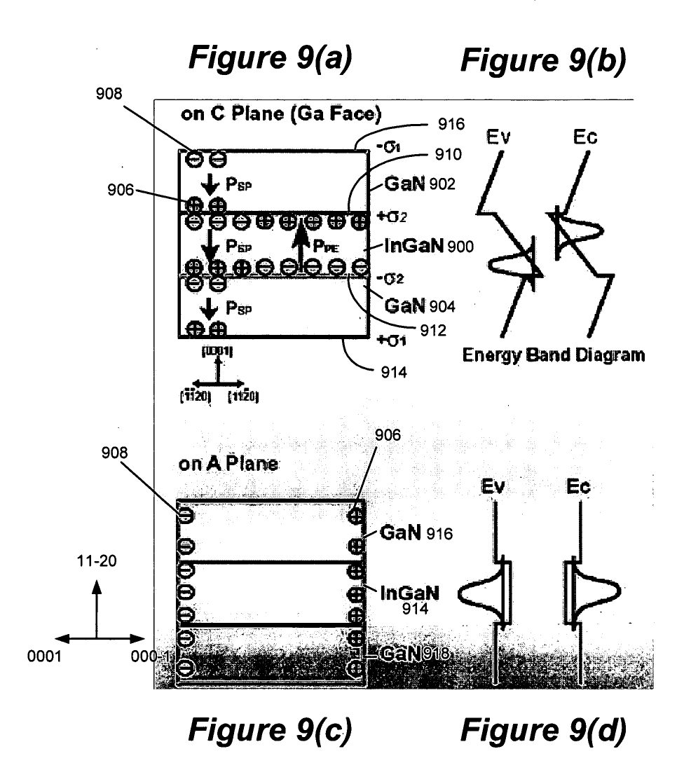

FIG. 9(a) shows the position or orientation of group III atoms and nitrogen atoms relative to one another within the quantum well layer (InGaN 900) and barrier layers (GaN 902, 904), wherein the InGaN 900 and GaN 902, 904 are grown on a c-plane or Ga face orientation (as indicated by the [0001] direction in FIG. 9(a)). Also shown is the direction of the spontaneous polarization Psp, caused by positive ionic charge 906 on the group III atoms and negative charge 908 on the nitrogen atoms, leading to positive sheet charge +σ₂, negative sheet charge −σ₂ at interfaces 910, 912, respectively, between the GaN 902, 904 and InGaN 900, positive sheet charge +σ₁ and negative sheet charge −σ₁ at interfaces 914, 916, respectively, and the direction the piezoelectric polarization P_{PE}.

FIG. 9(b) shows the valence band Eᵥ and conduction band E_{c} across the GaN/InGaN/GaN structure of FIG. 9(a), showing the position of electron and hole wavefunctions within the InGaN resulting from Psp and P_{PE}.

FIG. 9(c) shows the position or orientation of group III atoms and nitrogen atoms relative to one another within the quantum well layer (InGaN 914) and barrier layers (GaN 916, 918), wherein the InGaN 914 and GaN 916, 918 are grown on an a-plane (nonpolar plane, as indicated by the 11-20 direction). Positive ionic charge 906 on the group III atoms and negative charge 908 on the nitrogen atoms is shown.

FIG. 9(d) shows the valence band Eᵥ and conduction band E_{c} across the GaN/InGaN/GaN structure of FIG. 9(c), showing the unperturbed position of electron and hole wavefunctions within the InGaN 914, due to nonpolarity.

### REFERENCES

The following references are incorporated by reference herein.
[1] M. Funato, M. Ueda, Y. Kawakami, T. Kosugi, M. Takahashi, and T. Mukai, Jpn. J. Appl. Phys. 45 (2006) L659.
[2] R. Sharma, P. M. Pattison, H. Masui, R. M. Farrell, T. J. Baker, B. A. Haskell, F. Wu, S. P. DenBaars, J. S. Speck, and S. Nakamura, Appl. Phys. Lett. 87 231 110 (2005).
[3] H. Zhong, A. Tyagi, N. N. Fellows, R. B. Chung, M. Saito, K. Fujito, J. S. Speck, S. P. DenBaars, and S. Nakamura, Electronics Letters 43 (2007).
[4] H. Sato, A. Tyagi, H. Zhong, N. Fellows, R. B. Chung, M. Saito, K. Fujito, J. S. Speck, S. P. DenBaars, and S. Nakamura, Phys. Stat. Sol. (RRL) 1, 162-164 (2007).
[5] A. E. Romanov et. al., J. Appl. Phys., 100, p. 023522 (2006).
[6] H. Sato, R. B. Chung, H. Hirasawa, N. N. Fellows, H. Masui, F. Wu, M. Saito, K. Fujito, J. S. Speck, S. P. DenBaars, and S. Nakamura, Appl. Phys. Lett. 92, p. 221110 (2008).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A III-nitride based optoelectronic device grown on a nonpolar or semipolar substrate, comprising a light emitting diode (LED) or laser diode (LD) with an indium containing III-nitride quantum well layer, a peak emission wavelength longer than 500 nm, and a dislocation density, originating from interfaces between the indium containing III-nitride quantum well layer and III-nitride barrier layers, less than 9×10⁹ cm⁻².

2. The device of claim 1, wherein the LED or LD is grown on the substrate which is a miscut nonpolar or semipolar plane substrate.

3. The device of claim 1, wherein the LED or LD is grown on a surface of the substrate, and the surface is at an angle with respect to a nonpolar or semipolar plane that maintains a semipolar or nonpolar property of the quantum well layer.

4. The device of claim 3, wherein the surface is a miscut surface and the angle is a miscut angle.

5. The device of claim 1, wherein the LED or LD is grown on a nonpolar or semipolar plane of the substrate and the nonpolar or semipolar plane enables an indium composition and thickness of the quantum well layer such that the quantum well layer is capable of emitting the light having the peak emission wavelength longer than 500 nm.

6. The device of claim 1, wherein the LED or LD has a semipolar orientation.

7. The device of claim 6, wherein the quantum well layer is semipolar with an amount of piezoelectric and spontaneous polarization reduced as compared to a piezoelectric and spontaneous polarization of a c-plane indium containing quantum well layer.

8. The device of claim 1, wherein the quantum well layer's piezoelectric and spontaneous polarization vector lies in a plane of the interfaces, or at an angle less than 90 degrees inclined relative to the interfaces.

9. The device of claim 1, wherein the quantum well layer's piezoelectric and spontaneous polarization vector lies in a direction that causes a quantum confined stark effect (QCSE) that is reduced as compared to a QCSE created by a piezoelectric and spontaneous polarization vector aligned with a c-axis, thereby enabling the light having a wavelength longer than 500 nm.

10. The device of claim 1, wherein the peak emission wavelength is longer than 550 nm.

11. The device of claim 1, wherein the quantum well layer is an InGaN quantum well layer.

12. A method of fabricating a III-nitride optoelectronic device, comprising growing a nonpolar or semipolar device with a period of interruption time of more than 5 seconds between a well layer and barrier layers.

13. The method of claim 12, wherein the period of interruption time is more than 1 minute.

14. The method of claim 12, wherein a carrier gas is N₂ during the period of interruption time.

15. The method of claim 12, wherein a carrier gas is hydrogen (H₂) during the period of interruption time.

16. A light emitting device, comprising:
a first cladding layer material;
a second cladding layer material; and
an active layer material for emitting light having a wavelength longer than 500 nm, between the first cladding layer material and the second cladding layer material, wherein the first cladding material, second cladding layer material, and active layer material are such that the optical output power decreases, as a temperature of the light emitting device increases, to a lesser degree than the optical output power from the AlInGaP light emitting device.

17. A semipolar or nonpolar light emitting device, comprising a III-nitride quantum well layer with a reduced internal electric field, and higher indium composition for longer wavelength emissions, relative to [0001] III-nitride semiconductors.
